(19) United States
(12) Patent Application Publication
(10) Pub. No.: US 2010/0003827 A1
(43) Pub. Date: Jan. 7, 2010

(54) METHOD AND DEVICE FOR ETCHING A SUBSTRATE BY MEANS OF PLASMA

(75) Inventors: Wilhelmus Mathijs Marie Kessels, Tilburg (NL); Mauritius Cornelis Van De Sanden, Tilburg (NL); Michiel Alexander Blauw, Delft (NL); Freddy Roozeboom, Waalre (NL)

Correspondence Address: YOUNG & THOMPSON, 209 Madison Street, Suite 500, Alexandria, VA, 22314, US

(73) Assignee: TECHNISCHE UNIVERSITEIT EINDHOVEN, Eindhoven (NL)

(21) Appl. No.: 12/373,394

(22) PCT Filed: Jul. 12, 2007
(86) PCT No.: PCT/NL07/50348

§ 371 Date: Jun. 3, 2009

(30) Foreign Application Priority Data
Jul. 12, 2006 (NL) 2006/000355

(51) Int. Cl. H01L 21/3065; B44C 1/22

(52) U.S. Cl. 438/719; 216/67; 438/710; 156/345.51; 156/345.35; 257/E21.218

(57) ABSTRACT

In a method and device for etching a substrate by a plasma, the plasma is generated and accelerated at substantially sub-atmospheric pressure between a cathode and an anode of a plasma source (1) in a channel of system of at least one conductive cascaded plate between the cathode and anode. The plasma is released from the plasma source to a treatment chamber (2) in which the substrate (9) is exposed to the plasma. The treatment chamber is sustained at a reduced, near vacuum pressure during operation. An alternating bias voltage is applied between the substrate and the plasma during the exposure

The present invention relates to a method for etching a substrate by means of a plasma in which a plasma is generated by means of a plasma source and said substrate is subjected to an etching agent by means of said plasma.

In physics and chemistry, a plasma is typically an ionized gas, and is usually considered to be a distinct phase of matter in contrast to solids, liquids and gases. “Ionized” means that at least one electron has been dissociated from a proportion of the atoms or molecules of said gas. The free electric charges make the plasma electrically conductive so that it responds strongly to electromagnetic fields. The same free electric charges also make the plasma chemically highly reactive. As a result specific treatments may be carried out on the substrate which would otherwise be practically impossible or would have a considerable lower reaction rate. Because of the latter, plasma processing has been given increasing interest in for instance semiconductor technology for the manufacture of semiconductor devices and solar cells. It has been found that, with the aid of a reactive plasma, compounds may be deposited and substrate surfaces may be oxidized, etched, textured or otherwise modified with a very high degree of precision, detail and control, which explains the significance plasma processing has gained in nowadays semiconductor technology and related technical fields.

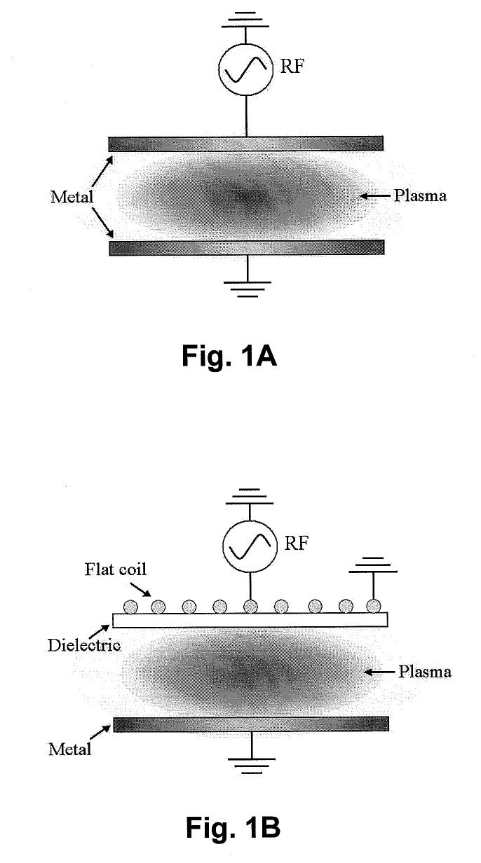

Conventional processes are using RF plasmas. In general, there are two different RF plasma configurations, namely capacitively coupled RF plasmas and inductively coupled RF plasmas. A capacitively coupled plasma system, is a system in which electrical power is capacitively coupled into the plasma. An example of a typical configuration of such a system is shown in FIG. 1A. The plasma is confined between two planar electrodes of which one is at ground and one is driven by an RF power source. In an inductively coupled plasma system, on the other hand, a coil is coupling RF power through a dielectric window, usually quartz, into the plasma. A configuration of an inductively coupled plasma system with a flat coil is shown in FIG. 1B. In both cases, the process pressure is more or less equal to the plasma source pressure due to the open configuration of the setup. Typically operating conditions and plasma parameters of these common plasma systems are as follows:

| | Capacitive | Inductive | |
|---|---|---|---|
| | RF Plasma | RF Plasma | |
| Plasma Source Pressure | 1-200 | 0.1-10 | Pa |
| Power | 50-2000 | 100-5000 | W |
| Gas flow | 0.1-5 | 0.1-5 | sccs |
| Frequency | 0.05-13.56 | 13.56-2450 | MHz |
| Ionization degree | 0.001-1 | 0.1-100 | ‰ |
| Process Pressure | 1-200 | 0.1-10 | Pa |
| Process Electron Density | 10¹⁵-10¹⁶ | 10¹⁶-10¹⁸ | m⁻³ |
| Process Electron Temperature | 1-5 | 2-7 | eV |

The ever decreasing dimensions in semiconductor devices demand an ever increasing precision of the processes to be used. Present lithographic techniques are in the far sub-micron range and other techniques used in the course of a semiconductor process are required to follow this trend. An important aspect in this respect is etching. Especially for attaining high packing densities, so called vias, trenches and other recesses at a substrate surface need to be etched with steep, preferably vertical walls in order to gain precision and to waist only a minimum of surface area. For this purpose an etching technique needs to be highly anisotropic, contrary to isotropic etching techniques like wet etching. The common plasma techniques, described above, however offer only a limited anisotropy which poses a barrier to diminishing feature size. Apart from that, the common plasma techniques suffer from a relatively poor ionization degree and flux, resulting in a relatively poor process rate, which renders these techniques commercially less attractive.

It is an object of the present invention to offer a method and device for localized etching a substrate by means of a plasma, which offers an improved precision and controllability together with a significant plasma density, such that aspect ratios and process rates beyond those of existing plasma techniques are attainable.

In order to achieve this object, the present invention provides for a method for etching a substrate by means of a plasma, wherein a plasma is generated and accelerated between a cathode and an anode of a plasma source in at least one channel of system of at least one conductive cascaded plate between said cathode and anode at substantially sub-atmospheric pressure, said plasma is released from at least one plasma source to a treatment chamber through a constricted passage opening, said substrate is exposed in said treatment chamber to an etching agent by means of said plasma, while said treatment chamber is sustained at a reduced, near vacuum pressure and a negative alternating bias voltage is applied between said substrate and said plasma during said exposure.

According to the invention a plasma is generated using a cascaded arc which is drawn, during operation, between the cathode and anode through the system of at least one cascaded plate. A direct current is drawn between cathode and anode. The generated plasma leaves the plasma source and flows to the substrate. The pressure in the central core of the cascaded arc is relative high (sub atmospheric), rendering plasma generation very effective. The ionization degree maybe up to typically 5-10%. This high density, highly ionized plasma is injected into the treatment chamber and is expanding towards the substrate. Due to the high velocity of the expanding plasma, the ionization degree is frozen in, while the pressure reaches the near vacuum process pressure, which is required for most etching processes. Typical plasma properties of the plasma source used in the method according to the invention are as follows:

| | | |
|---|---|---|
| Plasma Source Pressure | 10-200 | kPa |
| Power | 1000-5000 | W |
| Gas flow | 10-100 | sccs |
| Ionization degree | 0.1-100 | ‰ |
| Process Pressure | 1-100 | Pa |
| Process Electron Density | 10¹⁶-10¹⁹ | m⁻³ |
| Process Electron Temperature | 0.3 | eV |

The inventors have recognized that a further important parameter is the electron temperature. The moderate electron temperature of the plasma according to the invention, resulting from the specific plasma source used, allows a precise and relatively easy control of the ion and radical kinetics. Accordingly, the kinetic plasma properties near the substrate surface, like the ion/radical energy and direction, may be precisely tailored by applying a suitable bias voltage. This may advantageously be used for specifically anisotropically localized etching of a recess in a substrate.

For anisotropic plasma etching, for instance, ion bombardment perpendicular to the substrate is needed. This may be induced by applying a negative bias potential compared to plasma to the substrate. Such negative bias potential leads to acceleration of the positive charged ions towards the substrate. An alternating potential applied to the substrate attracts, depending on the sign of the potential, electrons or ions. Alternating this potential at high frequencies (MHz), the light and therefore highly mobile electrons as compared to the relative heavy and slow ions, create a time average negative potential at the substrate as the time average flux of electrons to the substrate must equal the time average flux of ions. As a result, a plasma sheath layer is formed between the plasma and the negatively biased substrate. Ions that enter the sheath layer are accelerated to the negative biased substrate that results in an ion bombardment.

Nevertheless, the time average current of the alternating bias signal is at least substantially zero so that no net current is drawn through the substrate, which could otherwise harm electrical or mechanical features already provided in said substrate. The bias voltage is externally induced, using a suitable source, in a suitable form. In order even more protect the substrate against such damage, a preferred embodiment of the method according to the invention is characterized in that, at least upon the application of said bias voltage, said substrate is isolated for a direct electrical current, particularly by connecting a capacitor between said substrate and ground potential. This isolation prevents a direct current to be drawn through the substrate, which could otherwise harm delicate structures already provided for in said substrate. Moreover a capacitively coupled substrate allows a fine adjustment of the bias voltage. The bias voltage will directly impose a mobility difference between the relatively fast electrons and relatively slow ions/radicals in the plasma, because the net current is maintained nil, which hence may be strictly controlled and tailored. Moreover, unintended charging of the non-conducting substrate will be prevented by a capacitor coupled to said substrate due to charge leveling imposed by the latter.

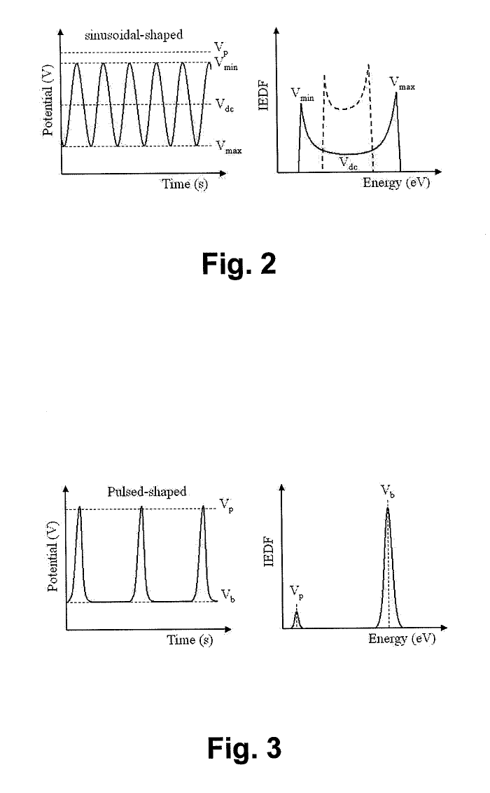

A first specific embodiment of the method according to the invention is characterized in that an oscillating bias voltage is applied between said substrate and said plasma. At very high frequencies, an ion needs many oscillation periods to cross the sheath layer, which results in ion energies closely around the time averaged field. At relative low radio frequencies, the time that an ion needs to cross the sheath layer is short compared the oscillation period. So the final energy of an ion varies depending on the time the ion entered the sheath. Ions entering the sheath when the sheath voltage is high gain more energy than ions entering the sheath when the sheath voltage is low. This results in a broad double-peaked Ion Energy Distribution Function (IEDF), which is shown schematically on the right in FIG. 2, the applied bias potential (V) being illustrated on the left. The IEDF narrows at increased frequency, shown by the dashed IEDF in FIG. 2, until it tends to a single peaked IEDF.

The time needed for an ion to cross the sheath layer is called the transit time. The transit time of an ion is determined by:

$${τ}_{ion} = 3 \overline{s} \sqrt{\frac{{M}_{ion}}{2 e {\overline{V}}_{s}}}$$

where s is the time averaged sheath thickness, Mᵢₒₙ is the ion mass, and Vₛ is the average potential drop in the sheath layer, i.e. the average between the plasma and the substrate potential during the bias oscillations, which is indicated in FIG. 2 with V_{dc}. A broad double-peaked region can now be defined as β=τ_{ion/}τ_{rf}<<1, whereas the IEDF becomes narrow when β=τ_{ion/}τ_{rf}<<1, τ_{rf} being the periodic length of the bias cycles.

In order to obtain a relatively narrow IEDF, a further specific embodiment of the method according to the invention is characterized in that a high frequency alternating bias voltage is applied having a frequency of the order of between 100 kHz and 100 MHZ and an amplitude of up to 500 V, particularly of the order of between 10 and 250 V. If, for instance, an oscillation frequency is used of about 13.5 MHz and the bias voltage is in the range of 10-250 V, the sheath layer thicknesses will typically be of the order of a few tenth of a millimetre to a few millimetre, which appears sufficiently small to attain the desired directional behaviour of the plasma

As shown in FIG. 2, the IEDF induced by an oscillating bias voltage is not perfectly single peaked. Depending on the frequency applied a narrow or more broadly double-peaked IEDF is obtained. The IEDF becomes nearly single-peaked only at very high frequencies. For high-density plasmas, such as the expanding thermal plasma used in the method according to the invention, the frequency necessary to attain a nearly single peaked IEDF is much higher than 30 MHz, which is impractical. A solution to this drawback is provided by a preferred embodiment of the method according to the invention which is characterized in that a pulsed bias voltage is applied between said substrate and said plasma, while said substrate is electrically isolated for a direct electrical current, particularly by connecting a capacitor between said substrate and ground potential. In this case the applied waveform has been manipulated so that the potential on the substrate is mostly constant. A schematic drawing of the pulsed potential at the substrate and the resulting ion energies is shown in FIG. 3.

Just as with an oscillating bias voltage, the time average current is zero, which means that the time average flux of ions must equal the time average flux of electrons. To achieve this, relatively short positive pulses are applied over time to momentarily collect the highly mobile electrons despite the overall negative substrate potential with respect to the plasma, attracting positively charged ions. During operation the substrate is dc isolated, particularly by connecting a capacitor between the substrate and ground potential, in order to block the dc component of the bias voltage. The ion current charges the capacitor, but, by slowly ramping down, the voltage compensates the increase of the potential difference over the capacitor. The charge loading capacity of the capacitor together with the amount of ramping determines the minimum frequency that can be used. The frequencies used in this embodiment of the method according to the invention can be in range of only a few hundred kHz. In silicon etch processes, the inventors have recognized that such a pulsed bias voltage moreover improves the etch selectivity of the etch plasma of silicon over silicon dioxide.

The present invention moreover relates to a device for etching a substrate with the aid of a plasma. According to the invention such a device is characterized by comprising at least one plasma source for generating a plasma, having a cathode and an anode, separated by a system of at least one conductive cascaded plate, comprising at least one substantial straight plasma channel between said cathode and said anode, a constricted release opening in open communication with said at least one plasma channel for releasing said plasma, a treatment chamber for receiving said plasma from said release opening, and a substrate holder in said treatment chamber for holding said substrate, at least during operation, in which said substrate holder is connected to a voltage source capable of applying a negative alternating bias voltage between said substrate holder and said plasma.

The invention will now be explained with reference to a number of exemplary embodiments and a drawing, wherein:

FIG. 1A-1B show a schematic representation of a plasma source of a conventional device for etching a substrate with the aid of a plasma;

FIG. 2 shows a schematic representation of an oscillating RF bias potential (left) and resulting double peaked ion energies (right);

FIG. 3 shows a schematic representation of a pulsed bias potential (left) and resulting single peaked ion energies (right);

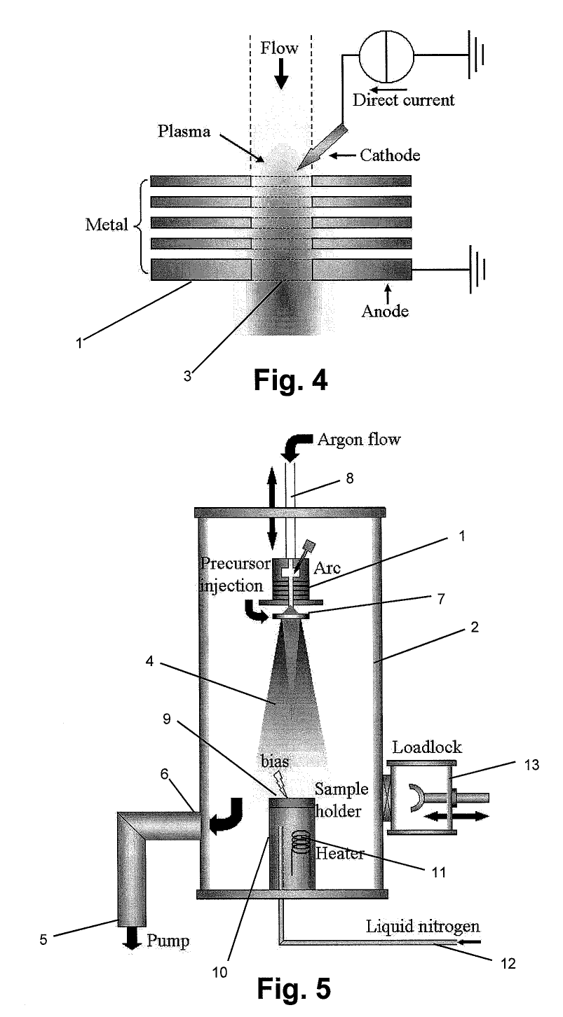

FIG. 4 shows a schematic representation of a plasma source of a specific example of a device for etching a substrate with the aid of a plasma according to the invention;

FIG. 5 shows a schematic representation of a specific example of a device according to the invention for etching a substrate with the aid of a plasma, incorporating the plasma source of FIG. 4;

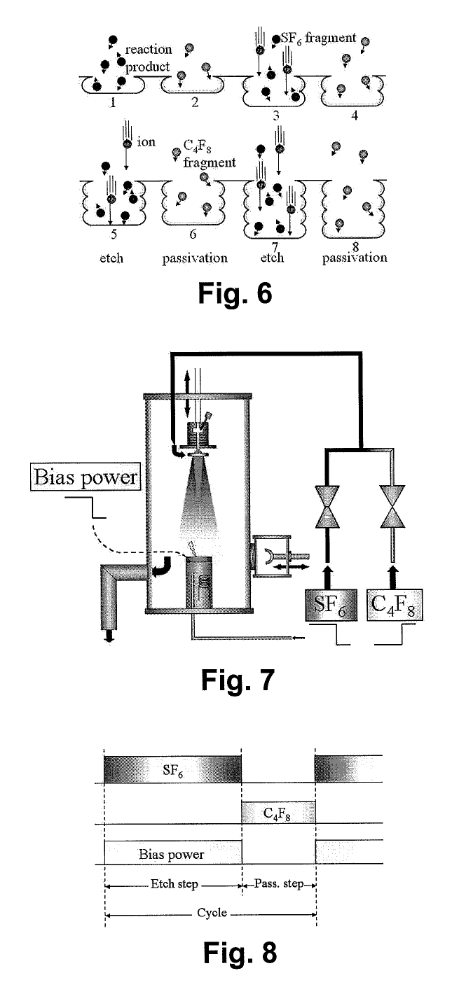

FIG. 6 a schematic representation of a first embodiment of the method according to the invention;

FIG. 7 a schematic representation of the setup of the device according to the invention applying the method of FIG. 6;

FIG. 8 a bias pulsing scheme as applied during the method of FIG. 6;

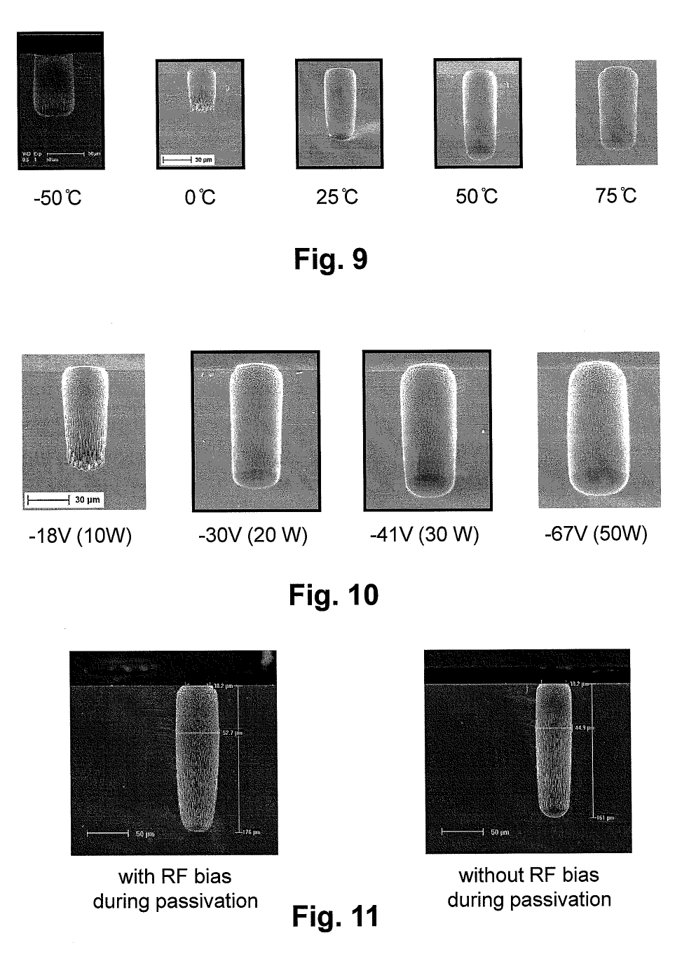

FIG. 9 SEM pictures of holes, etched at different temperatures using the method of FIG. 6;

FIG. 10 SEM pictures of holes, etched at different temperatures, using the method of FIG. 6;

FIG. 11 SEM pictures of holes, etched respectively with and without applying an RF bias voltage during the passivation step of the method of FIG. 6;

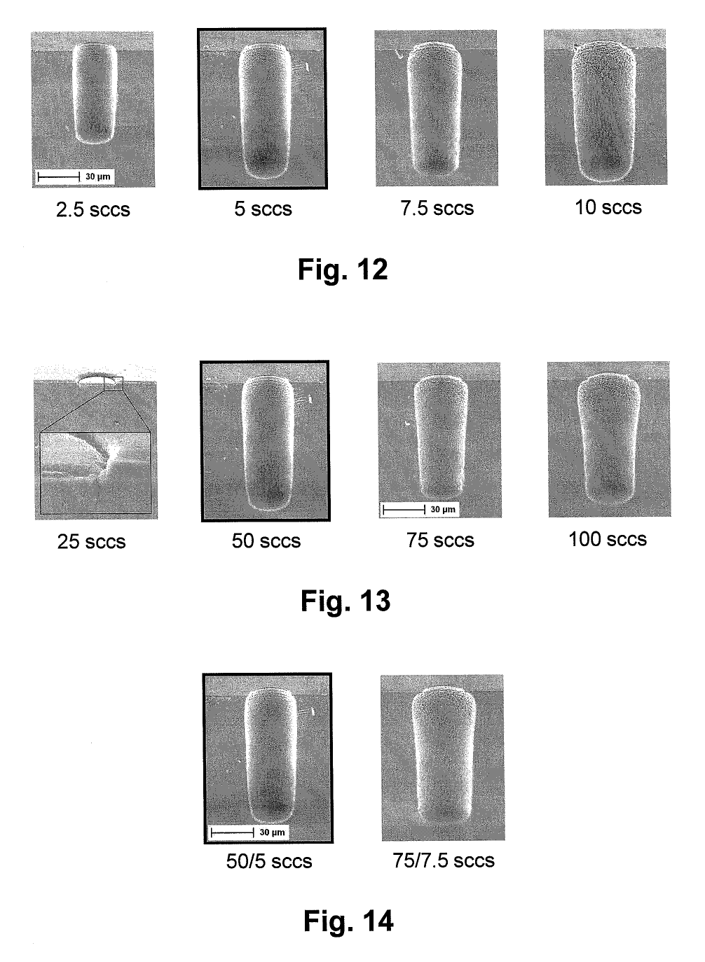

FIG. 12 SEM pictures of holes, etched at different fluorine flow rate using the method of FIG. 6;

FIG. 13 SEM pictures of holes, etched at different argon flow rate, using the method of FIG. 6;

FIG. 14 SEM pictures of holes, etched at different argon to fluorine flow rate ratios, using the method of FIG. 6;

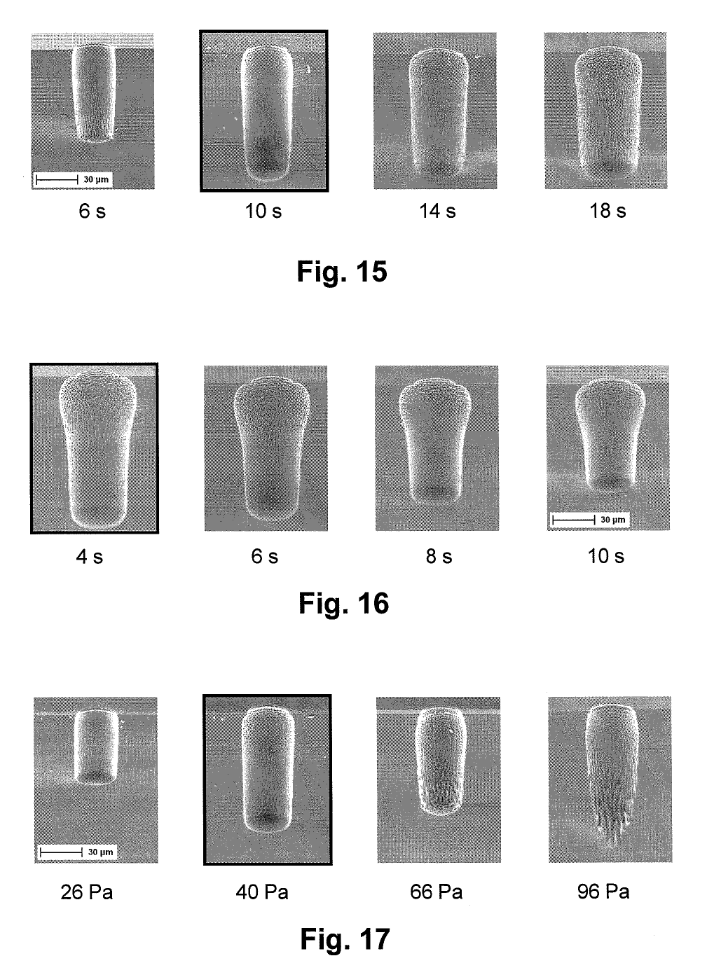

FIG. 15 SEM pictures of holes, etched at different etch times per cycle, using the method of FIG. 6;

FIG. 16 SEM pictures of holes, etched at different passivation times per cycle, using the method of FIG. 6;

FIG. 17 SEM pictures of holes, etched at different pressures, using the method of FIG. 6;

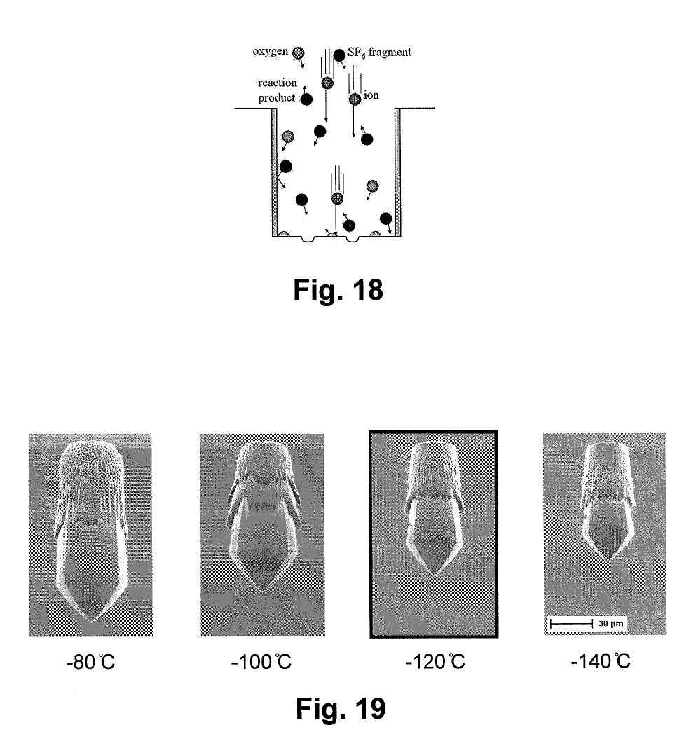

FIG. 18 a schematic representation of a second embodiment of the method according to the invention;

FIG. 19 SEM pictures of holes, etched at different temperatures, using the method of FIG. 18;

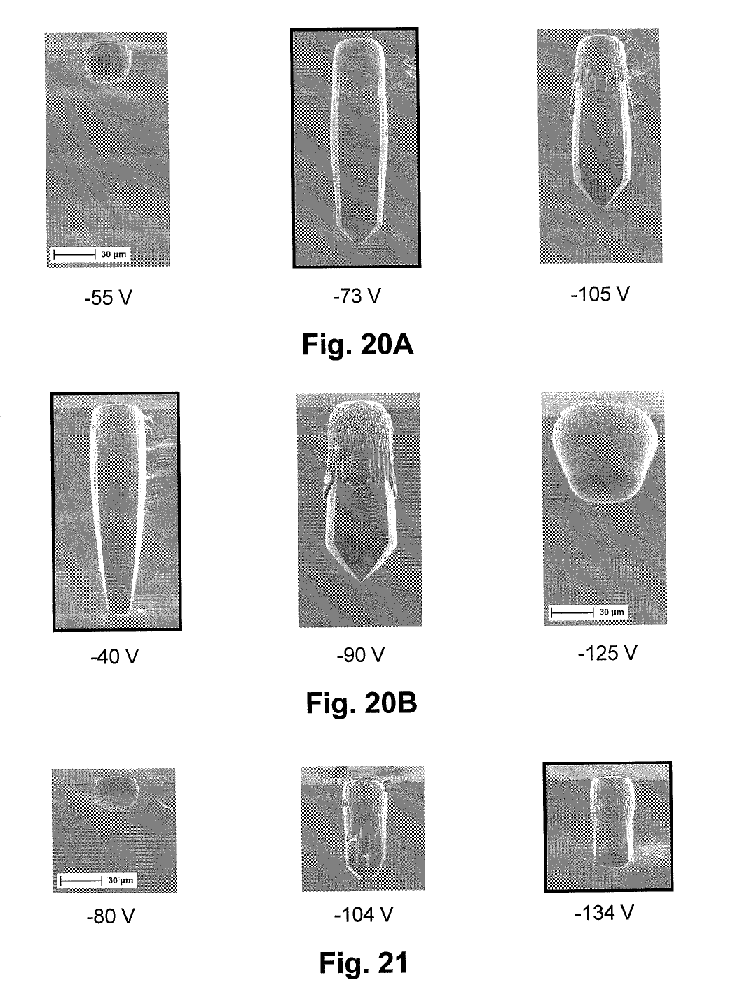

FIG. 20A SEM pictures of holes, etched at −120° C. with different oscillating RF bias voltages, using the method of FIG. 18;

FIG. 20B SEM pictures of holes, etched at −80° C. with different oscillating RF bias voltages, using the method of FIG. 18;

FIG. 21 SEM pictures of holes, etched at different pulsed bias voltages, using the method of FIG. 18;

FIG. 22 SEM pictures of holes, etched at different SF₆ flow rates with a constant O₂ flow, using the method of FIG. 18;

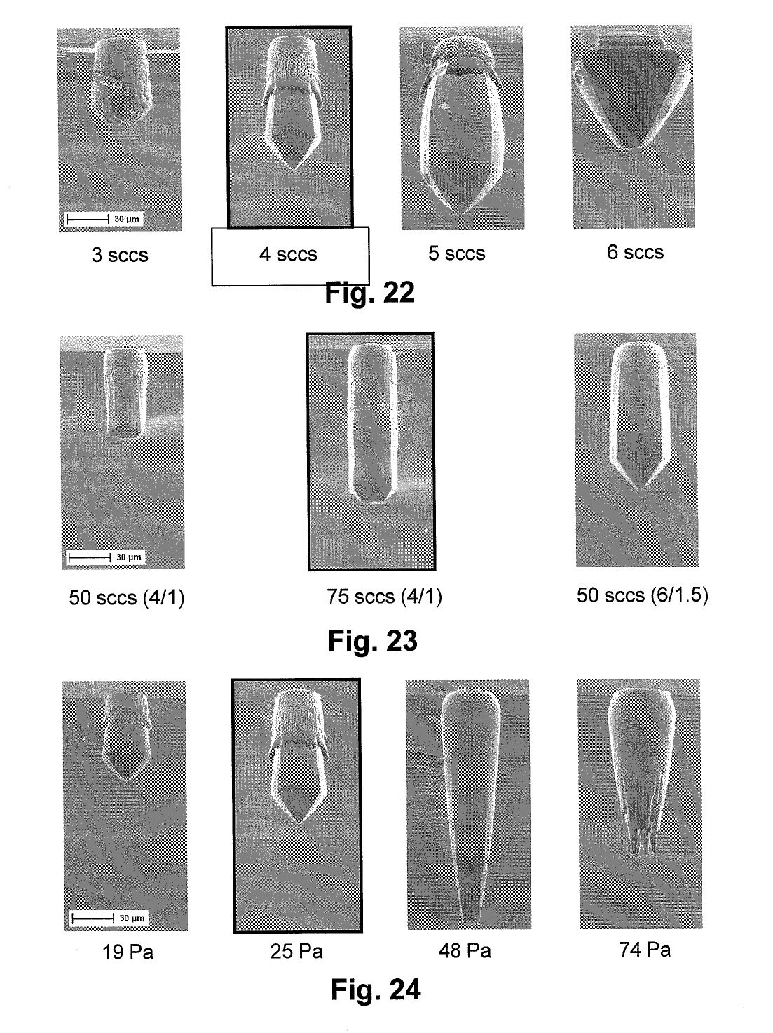

FIG. 23 SEM pictures of holes, etched at different precursor and carrier gas flow rates, using the method of FIG. 18; and

FIG. 24 SEM pictures of holes, etched at different pressures, using the method of FIG. 18.

It is noted that the drawings are purely schematically and not drawn to scale. In particular, some dimension may be exaggerated to more or less extent to more clearly express specific features. Corresponding features are provided with a same reference sign throughout the figures.

According to the invention a plasma is generated using a cascaded arc plasma source of the type as shown in FIG. 4. A high power direct current is drawn between a cathode and an anode of the plasma source through a system of one or more cascaded plates to generate a plasma arc 3. The plasma arc 3 is created in a carrier gas, in this example argon, which is fed into the plasma source via an inlet 8 and flows from the cathode to the anode. The carrier gas is injected with a relatively high flow rate of several tens of sccs (standard cubic cm per second). Due to this high flow rate, the pressure in the plasma source 1 is relative high (sub atmospheric), typically of the order of 10-200 kPa, such that plasma generation is very effective. The ionization degree may be up to 5-10%, which is very high compared to conventional RF plasmas. This high density plasma is expanding into a low pressure chamber, see FIG. 5, and is hence hereinafter referred to as Expanding Thermal Plasma (ETP) to distinguish it from more conventional RF plasmas generated by means of a capacitive or inductive RF plasma source. Due to the high velocity of the expanding plasma, the ionization degree is frozen in, while the pressure becomes low, as is required for most etch processes.

A schematic drawing of an embodiment of a device according to the invention for etching a substrate with a Expanding Thermal Plasma (ETP) is given in FIG. 5. The device comprises at least one high pressure plasma source 1, as depicted in FIG. 4, and a low pressure reactor chamber 2, typically with a volume of 125 litre into which a plasma jet 4 escaping the plasma source will expand. In the reactor chamber, a process pressure of the order of about 10-100 Pa is maintained by means of a roots pump 5 which is controlled by a gate valve 6. The capacity of the roots pump is about 1500 m³/h at the pump hole of the vessel. With a gas flow of 50 sccs, the pump can reach a pressure of 20 Pa in the reactor chamber, i.e. near vacuum. This means that the mean residence time of a gas particle in the reactor is about 0.5 seconds. With no gas flow, the roots pump reaches a pressure of about vacuum. When the reactor is in the standby mode, a turbo pump is used to reach a pressure of about 10⁻⁴ Pa.

The plasma source discharges the plasma through a constricted release opening. A few centimetre behind this release opening, a precursor or etching gas may be injected into the plasma by means of a ring 7 which is provided around the plasma jet 4. The precursor or etching gas will react with the argon ions in the reactor chamber. Charge transfer and dissociative recombination reactions produce reactive species from the precursor gas. Further downstream, the reactive species hit the substrate 9, which is placed on a substrate holder 10, comprising a mechanical chuck of aluminum or copper. With a heating element 11 and a duct 12, carrying liquid nitrogen through the chuck 10, the temperature of the substrate may be controlled.

A capacitor, not shown, is connected between the chuck 10 and ground potential, which is usually applied to the stainless steel walls of the treatment chamber 2, to electrically isolate the substrate 9 for DC electric currents. Because the substrate 9 is DC insulated, a bias power can safely be applied to the substrate. An external alternating bias voltage source, not shown, is connected between the substrate holder 10 and the reactor wall to induce an appropriate alternating bias voltage on the substrate 9 in accordance with the present invention.

For convenient exchange, the substrate 9 is provided on a substrate carrier, not shown, which is mechanically clamped to the chuck 10. A helium gas flow or thermally conducting paste in between the chuck and the substrate carrier provides for enhanced heat conduction between these two members. The substrate carrier, with the substrate 9 on it, can quickly be loaded and unloaded in the reactor via a load-lock chamber 13.

The device of FIGS. 4 and 5 may be used for locally creating deep holes, trenches or other recesses in a substrate with a high aspect ratio, i.e. with steep, almost vertical sidewalls. To this end an etchant is supplied via the ring 7 to the plasma. In order to attain a high anisotropic etching behaviour in a method for locally etching a recess in a substrate with the aid of a plasma, a first embodiment of the method according to the present invention is characterized in that alternately a first active agent and a second active agent are introduced in the plasma, the first agent being capable of etching the substrate and the second agent being capable of creating a protective layer on said substrate which is partly resistant to said first agent in said plasma. This first embodiment of the method according to the invention, hence, comprises alternating etching steps and passivating steps.

A specific example of this first embodiment of the method according to the invention will be explained hereinafter. In this example sulphurhexafluoride (SF₆) and fluorobutane (C₄F₈) are used as the first and second agent respectively on a silicon substrate. During an etch step, there may be a significant amount of isotropic etching as a result of the etch chemistry of fluorine with silicon in a SF6 plasma. However, before an etch step reaches a too high degree of lateral etching, it is interrupted by a passivating step.

During a passivating step, a C₄F₈ plasma deposits a, polytetrafluoroethylene (PTFE) like, fluorocarbon polymer on the surface of the silicon, which is protecting the silicon against fluorine. During a subsequent etch step, the ionic bombardment by the plasma, which is perpendicular to the substrate surface, is etching the polymer layer at the bottom of the hole and silicon etching can proceed in this vertical direction. Both etch mechanisms (polymer and silicon etching) take place during the etch step.

The first eight steps of this process, corresponding to four cycles, are schematically presented in FIG. 6. What basically looks like a repetition of a two step mechanism per cycle is actual a repetition of a three step mechanism. These three mechanisms are:

1. anisotropic fluorocarbon polymer etching in a SF₆ plasma;

2. isotropic silicon etching in the same SF₆ plasma; and

3. fluorocarbon polymer deposition in a C₄F₈ plasma.

A specific setup for carrying out the process of FIG. 6, using the device according to the invention, is depicted in FIG. 7.

The system has been expanded by two supplies for the first and second agent respectively. The first supply 21 carries the SF₆, whereas the second supply 22 is uses to feed C₄F₈ to the treatment chamber. For a proper gas flow control system, fast-response mass flow controllers 22,23, a short gas line 24 between the mass flow controllers and the ring 7 in the process chamber and an automatic operation system (software) are provided for. The substrate temperature may be controlled and kept constant during operation with the temperature control means 11,12 described with reference to FIG. 5.

The etch results for 15 minutes etching as a function of substrate temperature are shown in FIG. 9. This figure shows SEM pictures of etched holes at different temperatures. The diameter of the hole is 50 μm and 30 μm respectively in the first and further SEM-pictures. The temperatures are measured in the chuck. The real temperature at the substrate level may be a little higher. The highest etch rate is achieved at 50° C., which is about 6.5 μm/min. Lower temperatures of 25° C. and 0° C., at the same bias power of about 20 W at −32 Volt, result in lower etch rates of about 5.8 μm/min and 2.7 μm/min, respectively, but also lateral etching diminishes to substantial no lateral etching at −50° C. At 0° C., the bottom of the hole is rather rough, which may be avoided by increasing the bias power and voltage as demonstrated at −50° C., realised with a bias voltage of about −116 Volt during etching and passivation. The sample at −50° C. moreover shows an increased etch rate of about 5.9 μm/min as a result of the enhanced bias power, which is only little lower than the maximum observed etch rate at 50° C. The sample at 75° C., shows enhanced lateral etching, which is undesirable. The etch rate at 75° C. is a about 0.2 m/min lower than at 50° C. but, taking into account the lateral etching, the total etched volume is increased by 30%. In view of the above, a preferred embodiment of this first method according to the invention is characterized in that, during operation, the substrate is maintained at a substrate temperature of below 50° C., preferably between −50° C. and 50° C.

FIG. 8 shows a typical pulse scheme for applying an alternating bias voltage between the substrate and the plasma. The bias power is only applied in the etching steps and removed during the subsequent passivation step. Etch results as a function of bias voltage are shown in FIG. 10. This figure presents SEM pictures of etched holes with different RF bias voltages during a total etch time of 15 minutes. The diameter of the holes is 30 μm and for comparison all pictures have the same scale. Etch rates are approximate 5.2, 6.3, 6.8 and 6.5 μm/min for 15 minutes etching at bias voltages of −18V, −30V, −41V and −67V respectively. The maximum etch rate that is achieved is 6.8 μm/min at a bias voltage of −41 V. At a bias voltage of −18 V, the etch rate is reduced to 5.2 μm/min. At higher bias voltages the total depth etch rate decreases, along with some increased lateral etching as in the temperature series. In view of these figures, a preferred embodiment of this first method according to the invention is characterized in that during the introduction of said first agent an oscillating bias voltage in range between −30 and −50 Volt, particularly of around −40 Volt, is applied between said substrate and said plasma.

A further preferred embodiment of this first method according to the invention is characterized in that during the introduction of said second agent an oscillating bias voltage is applied between said substrate and said plasma, particularly in range between −150 and −170 Volt, more particularly of around −160 Volt. FIG. 11 shows SEM pictures of etched holes with (left) and without (right) applying a RF bias voltage during the passivation step. The diameter of the holes is 30 μm and for comparison both pictures have the same scale. Etch rates are about 5.9 μm/min and 5.4 μm/min respectively. The process is performed with a bias power of 50 W. This resulted in a bias voltage of approximately −70 V during the etch step. The bias voltage during the passivation step was approximately −165 V with a reflected power of 20 W. The total etch time was 30 minutes instead of the standard 15 minutes. Clearly, the etch rate decreases from 5.9 to 5.4 μm/min with an applied bias voltage during the passivation step. However, also lateral etching is decreased with an applied bias voltage during passivation. Although the etch rate is slightly decreased, a significantly better anisotropy is achieved.

Etch results as a function of different SF₆ flows are shown in FIG. 12 as SEM pictures of holes etched during 15 minutes with different SF₆ flow rates. The diameter of the holes is 30 μm and for comparison all pictures have the same scale. The observed etch rates are respectively approximately 4.8, 6.5, 6.8, 0.1 and 6.8 μm/min. To maintain the bias voltages in the order of −30 V, the bias powers are 10 W, 20 W, 20 W and 30 W respectively. This shows that the etch rate increases by increasing the SF₆ flow until a maximum of 6.8 μm/min at a flow of 7.5 sccs. Although the picture at 7.5 sccs seems to suggest differently, microscopic observations reveal that the depth is similar to the hole at 10 sccs and the lateral etching is comparable to the hole at 5 sccs SF₆. Significantly more lateral etching is observed at an SF₆ flow rate of 10 sccs. A further preferred embodiment of the first method according to the invention is hence characterized in that the first agent is introduced in said plasma with a flow rate of about 5-7.5 standard cubic centimetre per second (sccs).

Etch results as a function of the argon flow are shown in FIG. 13. During these tests, the valve of the roots pump was also varied to keep the pressure at the standard value of 40 Pa. This resulted in different partial pressures for the different gases. FIG. 13 shows SEM pictures of etched holes after 15 minutes etching with different argon flow rates. The diameter of the holes is 30 μm and for comparison all pictures have the same scale. The etch rates of the samples are approximately all equal at about 6.5 μm/min, except for the first one, where the etch rate reduces to zero. To maintain the bias voltages in the order of −30 V, the bias powers are 30 W, 20 W, 10 W and 10 W, respectively. Beyond 75 sccs significant more lateral etching is observed. Accordingly a further preferred embodiment of the first method according to the invention is characterized in that said plasma is generated with the aid of an inert carrier fluid, particularly an inert gas like argon, which is fed to said plasma source with a flow rate of between 50 and 75 standard cubic centimetre per second (sccs) and preferably of around 50 sccs.

Etch results as a function of both argon and SF₆ gas flow are shown in FIG. 14. The valve of the roots pump is varied to maintain the pressure at the standard value of 40 Pa.

Thus the absolute partial pressures are kept unchanged. By increasing the argon flow and keeping the arc current constant, the power input of the arc is increased by 600 W from 4125 to 4725 W. The etch rate increases from 6.5 μm/min at low flows to 7.8 μm/min at high flows. However, also the lateral etching is increased by the increased flows. Accordingly an optimal result is obtained around a relative flow of 50:5 sccs between the argon and the fluorine.

Etch results as a function of etch time per cycle are shown in FIG. 15. These SEM pictures show etched holes with different etch times per cycle over an overall etch time of 15 minutes. The diameter of the holes is 30 μm and for comparison all pictures have the same scale. The observed etch rates are about 4.9, 6.5, 6.7 and 6.9 μm/min for etch times of 6, 10,14 and 18 seconds respectively per cycle. This means that the etch rate increases from 4.9 μm/min to 6.9 μm/min for etch times per cycle from 6 to 18 seconds. This increase is not linearly dependent on the etch time per cycle. The highest increment, from 4.9 to 6.5 μm/min, is between 6 and 10 seconds per etch cycle. Beyond 10 seconds etch cycle time, more lateral etching is observed, which occurs at the expense of only a slightly higher vertical etch rate.

SEM pictures of etched holes with different passivation times per cycle during an overall process time of 15 minutes are shown in FIG. 16. The diameter of the holes is 30 μm and for comparison all pictures have the same scale. The observed etch rates are 7.8, 7.1, 6.4, and 5.9 μm/min respectively for passivation times of 4, 6, 8 and 10 seconds per cycle. The results moreover show that a longer passivation time hardly decreases lateral etching. However, the vertical etch rate significantly drops from 7.8 to 5.9 μm/min as passivation times rise from 4 seconds to 10 seconds. This decrease is mainly caused by an decrement of the net etch time. With a longer passivation time, the number of cycles for a constant total time is decreased, which results automatically in a shorter net etch time.

Based on the above figures a further preferred embodiment of the first method according to the invention is characterized in that said first and second agent are introduced during alternating time intervals, a first time interval for introduction of said first agent being about between 6 and 10 seconds and a second time interval for introduction of said second agent being about between 4 and 6 seconds. Further investigation of the etch and passivation times reveals that the total process time should preferably be less than about 15 minutes in order to maintain an optimal vertical etch rate and to avoid a severe surface roughness within the holes.

SEM pictures of etched holes with different pressures are shown in FIG. 17. The diameter of the holes is 30 μm and for comparison all pictures have the same scale. The estimated etch rates are 3.7, 6.5, 5.5 and 7.1 μm/min for pressures of 26, 40, 66 and 96 Pascal respectively. The bias voltages used in the last two samples is −24 V and −27V, different to the bias voltage of −32 V for the first two samples. The pictures show that the etch rate is almost doubled from 3.7 to 6.5 μm/min when the pressure is increased from 26 to 40 Pa. Further increase of the pressure gives almost no etch rate increment and causes rough hole bottoms. A further preferred embodiment of the first method according to the invention is hence characterized in that during operation a pressure is maintained at the substrate of about between 26 and 40 Pa, particularly of about 40 Pa.

In practice, especially favourable results are obtainable when conducting the preceding process with inter alia the following process parameters:

| Parameter | Value | |
|---|---|---|
| Temperature | −50° C.-50° C. | |
| RF bias power/voltage | 20 W/−32 V | |
| Argon flow | 50 | sccs |
| SF₆ flow | 5 | sccs |
| C₄F₈ flow | 4 | sccs |
| Total Etch time | 15 | minutes |
| Etch time per cycle | 10 | seconds |
| Passivation time per cycle | 4 | seconds |
| Process Pressure | 40 | Pa |
| Arc current | 75 | A |
| Arc distance | 60 | cm |

These values are indicated by the frames around the applicable SEM pictures in the drawings.

A second method for locally etching a recess in a substrate with the aid of said plasma and an etching mask is, according to the invention, characterized in that concurrently a first active agent and a second active agent are introduced in the plasma, the first agent being capable of etching the substrate and the second agent being capable of creating a protective layer on said substrate which is partly resistant to said first agent in said plasma. A particular example of this second method will be described hereinafter, with reference to the drawings, which example is, according to the invention, characterized in that said substrate comprises a silicon substrate, in that a fluorine containing compound is applied as said first agent, particularly sulphurhexafluoride (SF₆), and in that an oxidizing agent is applied as said second agent, in particular oxygen, and in that said substrate is maintained at a cryogenic temperature during operation.

In contrast to the previous process, this cryogenic etching process is continuous in that a first and second agent are applied concurrently, each having its own function. This has two major advantages, namely smooth sidewalls by the absence of the scallops which characterize the first process at each transition of the first to the second agent, and no process time loss due to separate passivation steps. In this example the process is used for cryogenic silicon etching and to this end uses a plasma composed of a SF₆/O₂ gas mixture.

At room temperature, this plasma mixture results in isotropic etching of the silicon caused by the normal isotropic etch behaviour of sulphurhexafluoride (SF₆). At low temperatures, particularly below −80° C., oxygen is starting to occupy more and more silicon sites in a competition with fluorine. These chemically attached oxygen atoms at the silicon surface form a silicon-oxide like passivation layer, which prevents fluorine radicals to etch the silicon such that silicon etching is reduced or even stopped. However, ion bombardment perpendicular to the substrate, induced by the substrate bias voltage according to the invention, removes the passivation layer at the bottom of the recess and etching proceeds primarily in the vertical direction only. FIG. 18 shows a schematically representation of this process.

SEM pictures of holes, etched at different temperatures using this process, are shown in FIG. 19. The diameter of the holes is 30 μm and for comparison all pictures have the same scale. The observed etch rates are 4.6, 3.9, 3.7 and 3.0 μm/min at temperatures of −80, −100, −120 and −140° C. respectively. This shows a gradual decrease of the vertical etch rate from −80 to −140° C. However, lateral etching at −80° C. is about 10 μm, and approximately zero at a temperature between −100° C. and −120° C. or below. A substrate temperature of −140 ° C. did not change the shape of the hole further, but shows a further decrease of the vertical etch rate. A preferred embodiment of this second method is, according to the invention, therefore characterized in that said substrate is maintained at a temperature in range between −100 and −140° C., particularly of about −120° C., during operation.

Etching as a function of an oscillating RF bias voltage has been investigated at two different substrate temperatures, i.e. at −120° C. and at −80° C. The results with a substrate temperature of −120° C. are shown in FIG. 20A, whereas FIG. 20B gives the results at −80° C. The diameter of the holes is 30 μm and for comparison all pictures have the same scale. The SEM pictures at −120° C., cf. FIG. 20A, reveal etch rates 0.8, 5.7 and 4.7 μm min at −55, −73 and −105 Volt RF bias voltage respectively. The different bias voltages are achieved with bias powers of respectively 30 W, 40 W and 60 W. At −80° C., cf. FIG. 20B, the etch rates are 5.6, 4.6 and 4.4 μm/min at −40, −90 and −125 Volt bias voltage respectively. These bias voltages are achieved with bias powers of respectively 20 W, 50 W and 70 W.

From these results it occurs that the best results are obtainable with a RF bias voltage roughly between −40 Volt and −90 Volt, specifically −73 Volt at −120° C. substrate temperature. When the bias voltage and therefore the ion-impact energy is too low, the de-passivation will stop. At a bias voltage of −90 V the etch rate is reduced to 4.7 μm/min. This is probably a result of more lateral etching and collar formation. Accordingly a further preferred embodiment of this second method according to the invention is characterized in that during the introduction of said first and second agent an oscillating bias voltage in range between −70 and −100 Volt, particularly of around −73 Volt, is applied between said substrate and said plasma.

Instead of an oscillating RF bias voltage, also a pulsed bias voltage may be applied. Etch results as a function of the pulsed bias voltage are shown in FIG. 21 as SEM pictures of etched holes with different “pulsed” bias voltages at a substrate temperature of −120° C. The diameter of the holes is 30 μm and for comparison all pictures have the same scale. The etch rates are 0.6, 0.3 and 2.5 μm/min at pulsed bias voltages of −80, −104 and −134 Volt respectively. The pulsed bias source operates at much lower frequencies than a RF pulsed bias source as used in the above examples and does not generate an additional plasma above the substrate. The SEM pictures of FIG. 21 reveal a highest vertical etch rate without substantial lateral etch at a pulsed bias voltage of −134 V. Accordingly a further preferred embodiment of this second method according to the invention is characterized in that during the introduction of said first and second agent a pulsed bias voltage of around −134 Volt, is applied between said substrate and said plasma.

FIG. 23 shows SEM pictures of etched holes with different SF₆ flow rates at a constant O₂ flow of 1 sccs, using an oscillating RF bias voltage. Except for the picture of 3 sccs, in which the hole diameter is 40 μm, the diameter of the holes is 30 μm. For comparison all pictures have the same scale. Varying the SF₆ flow while keeping the O₂ flow constant at about 1 sccs, changes the chemistry of the plasma and affects the etch rate as well as the sidewall profiles, i.e lateral etching. The etch rate with a 3 sccs SF₆ flow is 2.3 μm/min. Upon increasing the SF6 flow, the etch rate is increased to 3.7 μm/min at 4 sccs and to 4.6 μm/min at a SF₆ flow of 5 sccs. However, not only the vertical etch rate is increased; lateral etching is also increased which is attributed to a higher F/O ratio and therefore a weaker passivation. At an SF₆ flow rate of 6 sccs, the etching turns isotropic, which means that the F/O radial ratio is too high. As a result, the vertical etch rate at 6 sccs drops to 2.9 μm/min. Consequently a further preferred embodiment of the second method according to the invention is characterized in that the first agent and second agent are introduced in said plasma with a flow rate of about 4 and about 1 standard cubic centimetre per second (sccs) respectively.

The carrier gas argon as well as the precursor SF₆ and O₂ gas flows have been increased separately in order to determine their effect on the etch rate and profile. A pulsed bias source is used for applying a pulsed bias voltage between the substrate and the plasma. The results of these tests are shown in FIG. 23. The sulphurhexafluoride and oxygen gas flows are 4 sccs and 1 sccs respectively in the first two pictures and respectively 6.5 sccs and 1.5 sccs in the right most picture. By raising the carrier gas flow of argon by 50% from 50 sccs to 75 sccs, the etch rate increases from 2.5 to 4.3 μm/min. This is an increase of 72%. The passivating mechanism and therefore the lateral etching is not affected at all. By raising the precursor gasses by 50%, the etch rate increases from 2.5 to 4.1 μm/min, which is an increase of 64%. This time the passivating mechanism is affected and results in more lateral etching. The extra precursor gasses are probably dissociated with a different ratio, which changes the chemistry of the plasma. A further preferred embodiment of the second method according to the invention is hence characterized in that said plasma is generated with the aid of an inert carrier fluid, particularly an inert gas like argon, and in that the carrier gas is fed to said plasma source with a flow rate of around 50-75 standard cubic centimetre per second (sccs) at a gas flow of about 4 sccs and 1 sccs of the first and second agent respectively.

FIG. 24 shows SEM pictures of etched holes with different pressures. The diameter of the holes is 30 μm and for comparison all pictures have the same scale. The observed etch rates are 2.2, 3.7 and 11.6 μm/min during 15 minutes etching at 19, 25 and 48 Pa respectively and 13.0 μm/min for 10 minutes etching at 74 Pa. The different bias powers/voltages that are used are 50 W/−90 V, 50 W/−90 V, 70 W/−78 V and 90 W/−70 V respectively. Hence, the etch rate increases from 2.2 μm/min at a pressure of 19 Pa to 11.6 μm/min at a pressure of 48 Pa. This enormous etch rate increment is attributed to increased particle fluxes in the more narrow plasma jet as a result of the pressure rise (less expansion). At 74 Pa, however, more lateral etching occurs. Accordingly a further preferred embodiment of the second method according to the invention is characterized in that during operation a pressure is maintained at the substrate of about 25-50 Pa.

Based on the above tests, particularly favourable results may be obtained with the second embodiment of the method according to the invention applying the following process parameters:

| Parameter | Value | |
|---|---|---|
| Temperature | −120° | C. |
| RF bias power/voltage | 50 W/−90 V | |
| Argon flow | 50 | sccs |
| SF₆ flow | 4 | sccs |
| O₂ flow | 1 | sccs |
| Total etch time | 30 | minutes |
| Process Pressure | 25 | Pa |
| Arc current | 75 | A |
| Arc distance | 60 | cm |

The method and device according to the invention may advantageously be used for etching for instance holes, trenches or other recesses in a substrate body.

Although the invention has been described with reference to merely a limited number of embodiments, it will be appreciated that the invention is by no means limited in its application to the examples given. On the contrary many more variations and embodiments are feasible for a skilled person without departing from the scope and spirit of the invention. As such more than one plasma source may be used concurrently to increase the process rate and/or the surface area which may be etched and substrate other than silicon or semiconductor substrates may be treated, notably glass substrates and polymeric films.

1. Method for etching a substrate by means of a plasma, wherein a plasma is generated and accelerated between a cathode and an anode of a plasma source in at least one channel of system of at least one conductive cascaded plate between said cathode and anode at substantially sub-atmospheric pressure, said plasma is released from at least one plasma source to a treatment chamber through a constricted passage opening, said substrate is exposed in said treatment chamber to an etching agent by means of said plasma, while said treatment chamber is sustained at a reduced, near vacuum pressure and a negative alternating bias voltage is applied between said substrate and said plasma during said exposure.

2. Method according to claim 1 characterized in that at least upon the application of said bias voltage said substrate is isolated for a direct electrical current, particularly by connecting a capacitor between said substrate and ground potential.

3. Method according to claim 1 characterized in that an oscillating bias voltage is applied between said substrate and said plasma.

4. Method according to claim 3 characterized in that a high frequency alternating bias voltage is applied having a frequency of the order of between 100 kHz and 100 MHZ and an amplitude of up to 500 V, particularly of the order of between 10 and 250 V.

5. Method according to claim 2 characterized in that a pulsed bias voltage is applied between said substrate and said plasma, while said substrate is electrically isolated for a direct electrical current, particularly by connecting a capacitor between said substrate and ground potential.

6. Method according to claim 1 characterized in that said substrate is a semiconductor substrate, particularly a silicon substrate.

7. Method according to claim 6 for locally etching a recess in said substrate with the aid of said plasma using an etching mask, characterized in that alternately a first active agent and a second active agent are introduced in the plasma, the first agent being capable of etching the substrate and the second agent being capable of creating a protective layer on said substrate which is partly resistant to said first agent in said plasma.

8. Method according to claim 7 characterized in that a bias voltage is applied during the introduction of said first agent as well as during the introduction of said second agent.

9. Method according to claim 7 characterized in that said substrate comprises a silicon substrate, in that a fluorine containing compound is applied as said first agent, particularly sulphurhexafluoride (SF₆), and in that a fluorocarbon compound is applied as said second agent, in particular C₄F₈.

10. Method according to claim 9 characterized in that during operation the substrate is maintained at a substrate temperature below 50° C., and particularly between −50° C. and 50° C.

11. Method according to claim 9 characterized in that during the introduction of said first agent an oscillating bias voltage in range between −30 and −50 Volt, particularly of around −40 Volt, is applied between said substrate and said plasma.

12. Method according to claim 9, characterized in that during the introduction of said second agent an oscillating bias voltage is applied between said substrate and said plasma, particularly in range between −150 and −170 Volt, more particularly of around −160 Volt.

13. Method according to claim 9 characterized in that the first agent is introduced in said plasma with a flow rate of about 5-7.5 standard cubic centimetre per second (sccs).

14. Method according to claim 9 characterized in that said plasma is generated with the aid of an inert carrier fluid, particularly an inert gas like argon, which is fed to said plasma source with a flow rate of between 50 and 75 standard cubic centimetre per second (sccs) and preferably of around 50 sccs.

15. Method according to claim 9 characterized in that said first and second agent are introduced during alternating time intervals, a first time interval for introduction of said first agent being about between 6 and 10 seconds and a second time interval for introduction of said second agent being about between 4 and 6 seconds.

16. Method according to claim 9 characterized in that during operation a pressure is maintained at the substrate of about between 26 and 40 Pa, particularly of about 40 Pa.

17. Method according to claim 6 for locally etching a recess in said substrate with the aid of said plasma and an etching mask, characterized in that concurrently a first active agent and a second active agent are introduced in the plasma, the first agent being capable of etching the substrate and the second agent being capable of creating a protective layer on said substrate which is partly resistant to said first agent in said plasma.

18. Method according to claim 17 characterized in that said substrate comprises a silicon substrate, in that a fluorine containing compound is applied as said first agent, particularly fluorine (SF6), and in that an oxidizing agent is applied as said second agent, in particular oxygen, and in that said substrate is maintained at a cryogenic temperature during operation.

19. Method according to claim 18 characterized in that said substrate is maintained at a temperature in range between −100 and −140° C., particularly of about −120° C., during operation.

20. Method according to claim 19 characterized in that during the introduction of said first and second agent an oscillating bias voltage in range between −70 and −100 Volt, particularly of around −73 Volt, is applied between said substrate and said plasma.

21. Method according to claim 19 characterized in that during the introduction of said first and second agent a pulsed bias voltage of around −134 Volt, is applied between said substrate and said plasma.

22. Method according to claim 18 characterized in that the first and second agent are introduced in said plasma with a flow rate of about 4 and about 1 standard cubic centimetre per second (sccs) respectively.

23. Method according to claim 22 characterized in that said plasma is generated with the aid of an inert carrier fluid, particularly an inert gas like argon, and in that the carrier gas is fed to said plasma source with a flow rate of around 50-75 standard cubic centimetre per second (sccs).

24. Method according to claim 18 characterized in that during operation a pressure is maintained at the substrate of about 25-50 Pa.

25. Device for etching a substrate with the aid of a plasma, comprising at least one plasma source for generating a plasma, having a cathode and an anode, separated by a system of at least one conductive cascaded plate, comprising at least one substantial straight plasma channel between said cathode and said anode, a constricted release opening in open communication with said at least one plasma channel for releasing said plasma, a treatment chamber for receiving said plasma from said release opening, and a substrate holder in said treatment chamber for holding said substrate, at least during operation, in which said substrate holder is connected to a voltage source capable of applying an alternating bias voltage between said substrate holder and said plasma.

26. Device according to claim 25 characterized in that the voltage source is capable and devised for generating an oscillating or pulsed alternating bias voltage at a suitable high frequency.

27. Device according to claim 25 characterized in that the substrate holder is DC (direct current) isolated with respect to the processing chamber, particularly in that a capacitor is connected between the substrate holder and ground potential.

28. Device according to claim 25, characterized in that the substrate holder is provided with temperature control means.

29. Device according to claim 28 characterized in that the temperature control means comprise heating means and cooling means.

30. Device according to claim 29 characterized in that the heating means comprise an electric heater and in that the cooling means comprise at least one duct for a liquidized gas, particularly liquid nitrogen.
